(19) United States
(12) Patent Application Publication
(10) Pub. No.: US 2016/0071604 A1
(43) Pub. Date: Mar. 10, 2016

(54) SEMICONDUCTOR MEMORY DEVICE

(71) Applicant: KABUSHIKI KAISHA TOSHIBA, Tokyo (JP)

(72) Inventors: Yoichiro KURITA, Tokyo (JP); Hiroyuki SUTO, Kamakura Kanagawa (JP); Fuminori KIMURA, Yokohama Kanagawa (JP)

(73) Assignee: KABUSHIKI KAISHA TOSHIBA, Tokyo (JP)

(21) Appl. No.: 14/642,530

(22) Filed: Mar. 9, 2015

Related U.S. Application Data
(60) Provisional application No. 62/048,052, filed on Sep. 9, 2014.

(51) Int. Cl. G11C 16/20; G11C 11/56

(52) U.S. Cl. CPC G11C 16/20; G11C 11/5628

(57) ABSTRACT

According to one embodiment, a semiconductor memory device includes: a first component including a controller which issues an instruction complying with a NAND interface; and a second component including a first NAND flash memory which is controlled by the instruction, the second component being removable from the first component.

### CROSS-REFERENCE TO RELATED APPLICATIONS

This application claims the benefit of U.S. Provisional Application No. 62/048,052, filed Sep. 9, 2014, the entire contents of which are incorporated herein by reference.

### FIELD

Embodiments described herein relate generally to a semiconductor memory device.

### BACKGROUND

As a memory system used in a computer system, an SSD (Solid State Drive) including NAND flash memories is known.

### BRIEF DESCRIPTION OF THE DRAWINGS

FIG. 1 is a block diagram of a semiconductor memory device according to an embodiment;

FIG. 2 is a view showing the connected state of the components of the semiconductor memory device according to an embodiment;

FIG. 3 is a view showing the detached state of the components of the semiconductor memory device according to an embodiment;

FIG. 4 is a functional block diagram of a storage control device according to an embodiment;

FIG. 5 is a view concerning data movement in the semiconductor memory device according to an embodiment;

FIG. 6 is a flowchart showing the first example of the write operation of the semiconductor memory device according to an embodiment;

FIG. 7 is a flowchart showing the second example of the write operation of the semiconductor memory device according to an embodiment;

FIG. 8 is a flowchart showing the exchange mode of the removable memory of the semiconductor memory device according to an embodiment;

FIG. 9 is a view concerning parallel wiring connection of the semiconductor memory device according to an embodiment;

FIG. 10 is a view concerning serial wiring connection of the semiconductor memory device according to an embodiment;

FIG. 11 is a block diagram showing arrangement example 1 of a memory system according to an embodiment; and

FIG. 12 is a block diagram showing arrangement example 2 of the memory system according to an embodiment.

### DETAILED DESCRIPTION

In general, according to one embodiment, a semiconductor memory device includes: a first component including a controller which issues an instruction complying with a NAND interface; and a second component including a first NAND flash memory which is controlled by the received instruction, the second component being removable from the first component.

An embodiment will now be described with reference to the accompanying drawings. In the following description, the same reference numerals denote the same parts throughout the drawings.

### [1] Semiconductor Memory Device 100

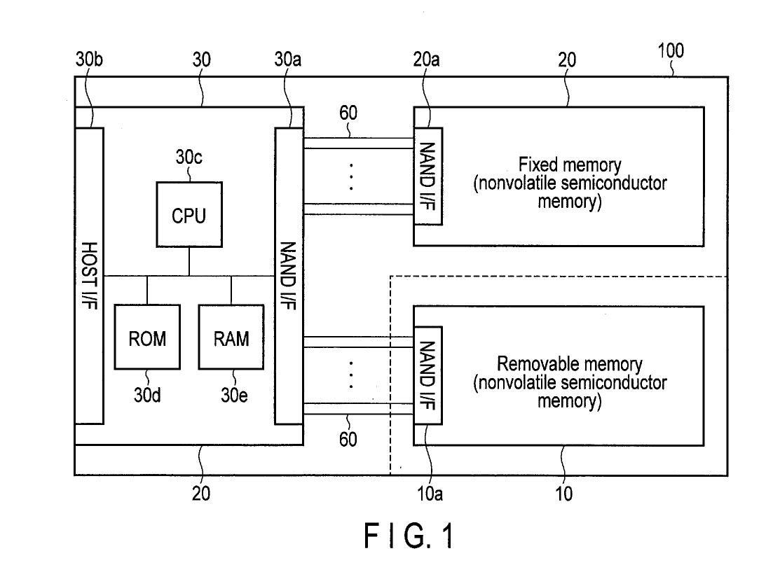

A semiconductor memory device 100 according to an embodiment will be described with reference to FIGS. 1, 2, and 3. As the semiconductor memory device 100, for example, an SSD is usable. The SSD is a drive which uses a nonvolatile semiconductor memory, such as a NAND flash memory, as an external storage device.

As shown in FIG. 1, the semiconductor memory device 100 includes a removable memory 10 and a fixed memory 20, each of which includes a nonvolatile semiconductor memory, and a controller (storage control device) 30.

The nonvolatile semiconductor memory in each of the removable memory 10 and the fixed memory 20 is, for example, a NAND flash memory. The NAND flash memory includes a plurality of memory cells and nonvolatilely stores data. The NAND flash memory is used as a storage unit to store user data, programs, internal data of a memory system, and the like. More specifically, the NAND flash memory stores data designated on the side of a host apparatus (not shown) or data that should nonvolatilely be stored such as firmware programs and management information that manages data storage positions in the NAND flash memory. In the NAND flash memory, erase is done on a block basis, and write and read are done on a page basis. The NAND flash memory includes a memory cell array in which a plurality of memory cells are arranged in a matrix. The memory cell array is formed by arranging a plurality of physical blocks that are the data erase units. In the NAND flash memory, data write and read are performed for each physical page. A physical page is formed from a plurality of memory cells. A physical block (memory block or data block) is formed from a plurality of physical pages.

The removable memory 10 and the fixed memory 20 include NAND interface (I/F) circuits 10a and 20a, respectively. The NAND interface circuits 10a and 20a control signal reception/transfer to/from the controller 30. At the time of data write, the NAND interface circuits 10a and 20a receive a control signal (write command and address) and write data from the controller 30. At the time of data read, the NAND interface circuits 10a and 20a receive a control signal (read command and address) from the controller 30 and transfers read data to the controller 30.

The controller 30 instructs the NAND flash memories to do read, write, erase, or the like in response to an instruction from the host apparatus (not shown). The controller 30 manages the memory space of each NAND flash memory.

The controller 30 includes a NAND interface (I/F) circuit 30a, a host interface (I/F) circuit 30b, a CPU (Central Processing Unit) 30c, a ROM (Read Only Memory) 30d, and a RAM (Random Access Memory) 30e.

The NAND interface circuit 30a is connected to the NAND flash memories (removable memory 10 and fixed memory 20) via NAND buses 60 and controls communication with the NAND flash memories. The NAND interface circuit 30a issues an instruction complying with the NAND interface. The NAND flash memories receive the instruction and are controlled by the received instruction.

For example, a chip enable signal /CE, a command latch enable signal CLE, an address latch enable signal ALE, a write enable signal /WE, a read enable signal /RE, a write protect signal /WP, and a power-on select signal PSL are transmitted/received between the NAND interface circuit 30a and each NAND flash memory. /CE is a signal used to enable the NAND flash memory. CLE is a signal that notifies the NAND flash memory that an input signal is a command. ALE is a signal that notifies the NAND flash memory that an input signal is an address signal. /WE is a signal used to cause the NAND flash memory to receive an input signal. /RE is a signal used to extract an output signal from the NAND flash memory. /WP is a signal used to protect the NAND flash memory from write and erase. PSL is a signal used when initializing the NAND flash memory.

The host interface circuit 30b is connected to the host apparatus (not shown) and controls communication with the host apparatus. The host interface circuit 30b transfers instructions and data received from the host apparatus to the CPU 30c. The host interface circuit 30b transfers data to the host apparatus in response to an instruction from the CPU 30c. As the host interface circuit 30b, for example, a SATA interface or the like is used. The SATA interface is an interface complying with the Serial Advanced Technology Attachment standard. Note that the interface standard may be not SATA but SAS (Serial Attached SCSI) and PCIe (PCI Express) or the like.

The CPU 30c controls the overall operation of the controller 30. For example, upon receiving a read instruction from the host apparatus, the CPU 30c issues, in response to it, a read instruction based on the NAND interface. This also applies to write and erase. The CPU 30c executes various kinds of processing for managing the NAND flash memories, such as wear leveling, a management of the data erase count as the data rewrite count of each block. The CPU 30c executes various kinds of operations, for example, data encryption processing and randomization processing.

The ROM 30d stores a control program to be controlled by the CPU 30c, and the like. The RAM 30e is used as the work area of the CPU 30c and temporarily stores a control program and the like. The RAM 30e has a logical address management table. The logical address management table includes the logical address/physical address conversion table which changes a logic block address into a physical block address, and the data erase count of the physical block.

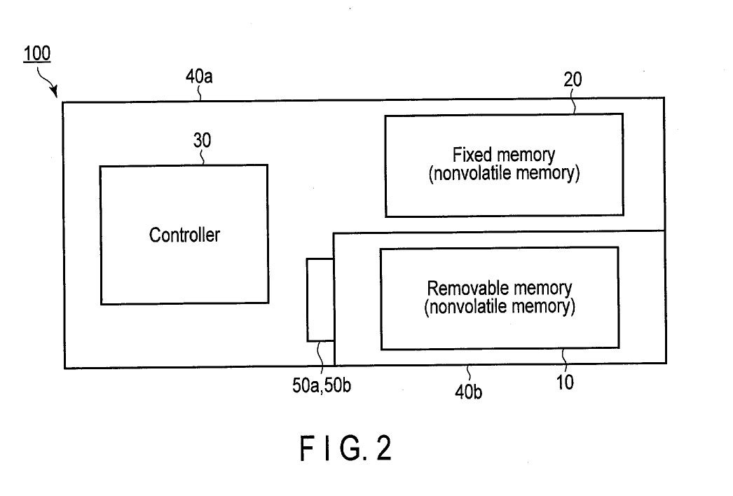

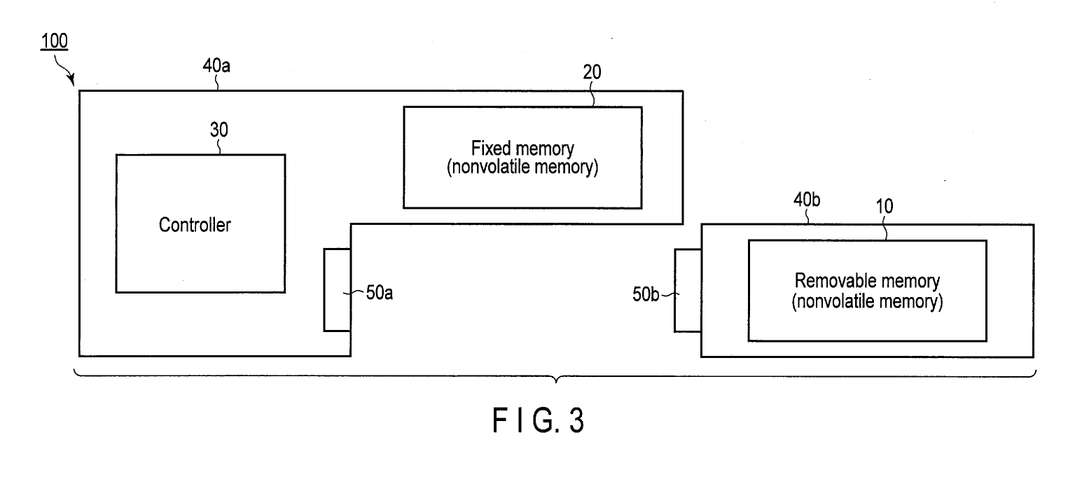

In the semiconductor memory device 100 according to the above-described embodiment, as shown in FIGS. 2 and 3, the fixed memory 20 and the controller 30 are arranged on a first component 40a, and the removable memory 10 is arranged on a second component 40b. Hence, the fixed memory 20 and the controller 30, and the removable memory 10 are provided on the different components 40a and 40b. In other words, the removable memory 10 is mounted on a circuit board (for example, motherboard) different from the circuit board on which the fixed memory 20 and the controller 30 are mounted. A connector 50b of the second component 40b can be inserted into or removed from a connector 50a of the first component 40a. The second component 40b can be removable from the first component 40a.

The removable memory 10 is formed from, for example, a memory having a high endurance, and an eMLC (enterprise Multi Level Cell) or SLC (Single Level Cell) type NAND flash memory or the like is used. Note that the memory having a high endurance indicates, for example, a memory whose read error rate after a predetermined number of data are rewritten is low.

The fixed memory 20 is formed from, for example, a memory having a low endurance and a large capacity, and an advanced TLC (Tree Level Cell) type NAND flash memory or the like is used.

Data in the removable memory 10 and the fixed memory 20 are distributed by the controller 30 in accordance with the rewrite count (frequency) of block. The removable memory 10 thus holds data of block whose rewrite count is equal to or higher than a reference value A, and the fixed memory 20 thus holds data of block whose rewrite count is lower than the reference value A. Hence, the removable memory 10 holds data whose rewrite count is higher than that of data in the fixed memory 20.

The first component 40a does not have the fixed memory 20 and has only the controller 30. A plurality of second components 40a may be inserted into the first component 40a.

### [2] Controller 30

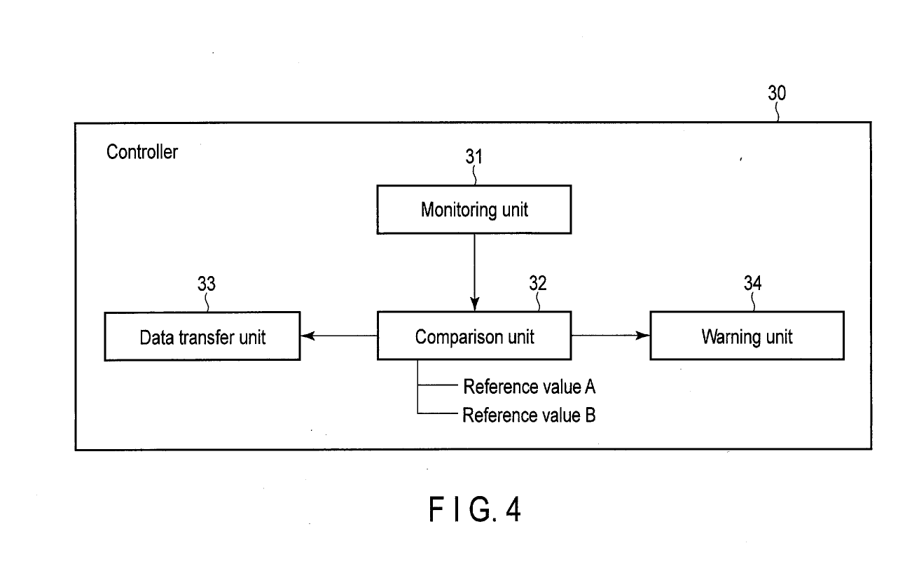

The controller 30 according to an embodiment will be described with reference to FIG. 4. Note that the controller 30 is an independent IC chip that manages data input/output to/from the memory cells of the removable memory 10 and the fixed memory 20, and is different from peripheral circuits arranged around the memory cells.

As shown in FIG. 4, the controller 30 is configured to execute a program including a monitoring unit (monitor) 31, a comparison unit (comparator) 32, a data transfer unit 33, and a warning unit 34 using the CPU 30c. This program is stored in, for example, the ROM 30d or the RAM 30e.

The monitoring unit 31 monitors the rewrite count of data in the removable memory 10 and the number of defective blocks in the removable memory 10. Note that the monitoring unit 31 can also monitor the rewrite count of data in the fixed memory 20. In cases where the nonvolatile semiconductor memory is the NAND flash memory, the data rewrite count may consider the erase count of each block, for example.

The comparison unit 32 has the reference value A for the data rewrite count, and a reference value B for the number of defective blocks. The comparison unit 32 compares the data rewrite count with the reference value A, and compares the number of defective blocks with the reference value B. The reference values A and B are stored in, for example, the ROM 30d or the RAM 30e. Note that the reference values A and B can be generated in the controller 30 based on control information or input from outside the controller 30.

The data transfer unit 33 controls data movement between the removable memory 10 and the fixed memory 20 in accordance with the comparison result of the data rewrite count and the reference value A. More specifically, the data transfer unit 33 moves data of high rewrite count to the removable memory 10 having a high endurance, and moves data of low rewrite count to the fixed memory 20 having a low endurance. The data movement of the data transfer unit 33 is done by, for example, the NAND interface circuit 30a.

The warning unit 34 gives a warning in accordance with the comparison result of the number of defective blocks and the reference value B. More specifically, when the number of defective blocks is equal to or larger than the reference value B, the warning unit 34 gives a warning by alarm or the like.

The controller 30 is not limited to the above-described functions and performs garbage collection or wear leveling for the removable memory 10 and the fixed memory 20 as needed.

When rewriting data in the NAND flash memories of the removable memory 10 and the fixed memory 20, overwrite in the memory cells cannot be performed. For this reason, write is done for free cells, and the original cells are disabled. In addition, since erase can be done only on a block basis, the disabled cells in a block grow in a dotted pattern. In this case, necessary data in the block are sorted out and copied to another block, and the original block is erased (flashed) at once. In this way, the controller 30 performs garbage collection.

Wear leveling is executed as needed in each unit of the removable memory 10 and the fixed memory 20. Data is moved from a cell of high rewrite count to a cell of low rewrite count, thereby uniforming the rewrite counts of all cells in each unit.

Note that the controller 30 may be configured to include dedicated hardware circuits having specific functions for the above-described monitoring unit 31, comparison unit 32, data transfer unit 33, and warning unit 34.

### [3] Operation

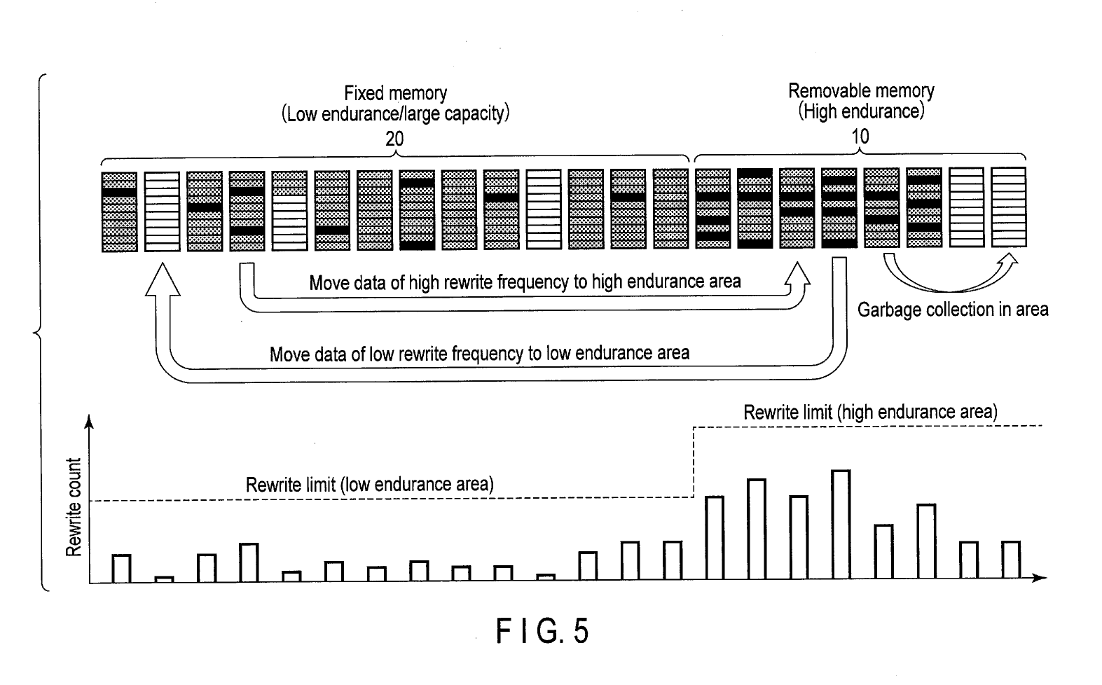

As shown in FIG. 5, in an embodiment, data of high rewrite count are moved to the area (removable memory 10) having a high endurance, and data of low rewrite count are moved to the area (fixed memory 20) having a low endurance.

### [3-1] First Example of Write Operation

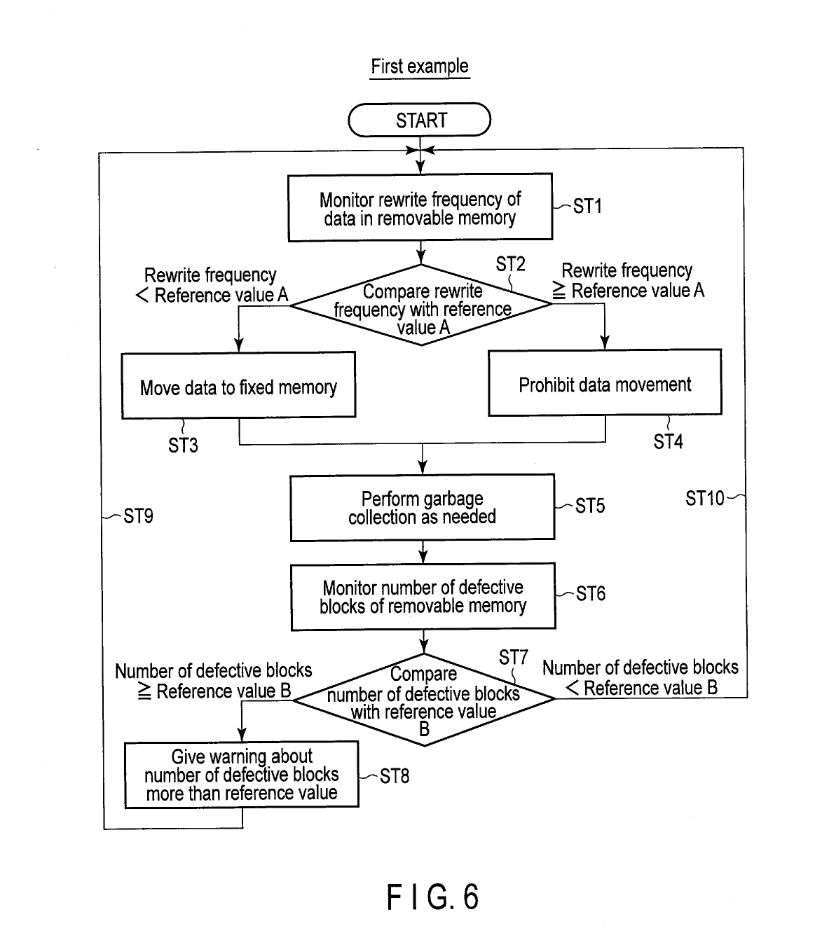

The first example of the write operation will be described with reference to FIG. 6. In the first example, at the time of data write, all data are written on the side of the removable memory 10 first, and data of low rewrite count are moved to the fixed memory 20.

First, the controller 30 monitors the rewrite count of data in the removable memory 10 on, for example, a file basis (step ST1).

The controller 30 compares the rewrite count of the data with the reference value A (step ST2). As a result, the controller 30 performs the following processing.

If the rewrite count of the data is lower than the reference value A (rewrite count<reference value A), the data is moved to the fixed memory 20 (step ST3). On the other hand, if the rewrite count of the data is equal to or higher than the reference value A (rewrite count≧reference value A), the data is maintained in the removable memory 10 (step ST4).

Next, the controller 30 performs garbage collection for the removable memory 10 and the fixed memory 20 as needed (step ST5).

Next, the controller 30 monitors the number of defective blocks in the removable memory 10 (step ST6).

The controller 30 compares the number of defective blocks with the reference value B (step ST7). As a result, the controller 30 performs the following processing.

If the number of defective blocks reaches the reference value B (number of defective blocks≧reference value B), a warning about the number of defective blocks more than the reference value is given by alarm or the like (step ST8). After that, the rewrite count is monitored again, and the processing is repeated from step ST1 again (step ST9). On the other hand, even when the number of defective blocks is smaller than the reference value B (number of defective blocks<reference value B), the process returns to step ST1 again, and the processing is repeated from rewrite count monitoring again (step ST10).

The reference value A does not always necessarily need to be constant, and can be changed. For example, as a result of moving data, in cases where the free space of the fixed memory 20 becomes small, for example, ⅕ or less of the whole, the reference value A falls 20%, for example. Thereby, the amount of movements of the data from the removable memory 10 to the fixed memory 20 can increase. As a result, the free space of the fixed memory 20 can increase, and the operation of the system can stabilize. The reverse operation is also possible. Change of the free space of the removable memory 10 and the fixed memory 20, the change in the reference value A are performed by management and control of the controller 30.

### [3-2] Second Example of Write Operation

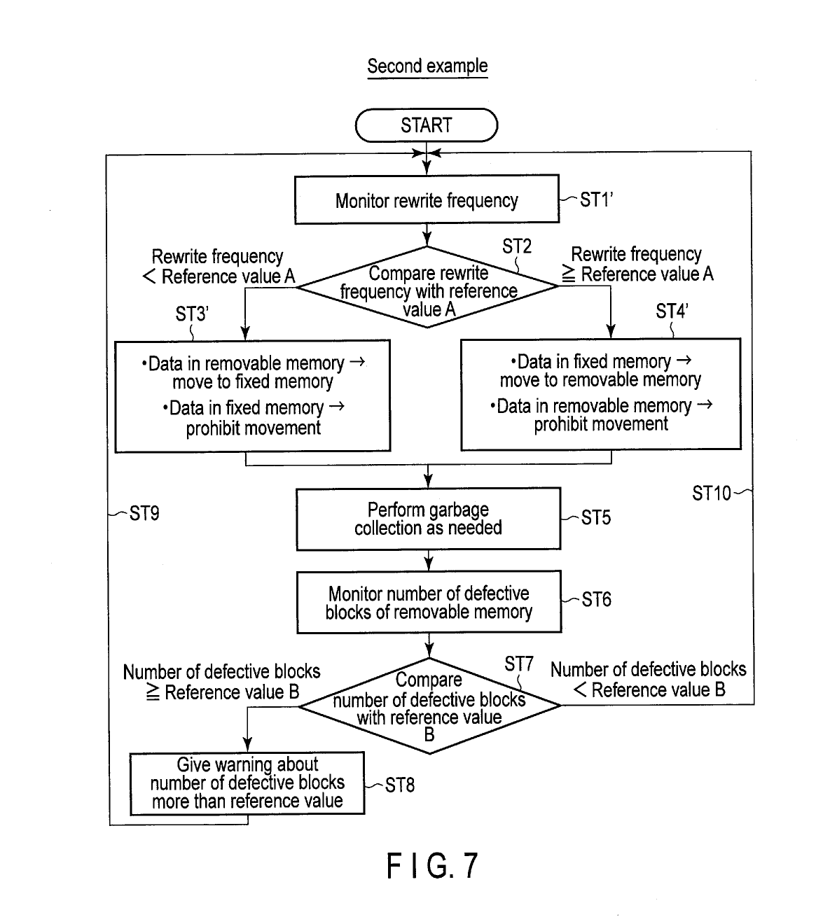

The second example of the write operation will be described with reference to FIG. 7. In the second example, at the time of data write, data is written in one of the removable memory 10 and the fixed memory 20. Data of high rewrite count is moved to the removable memory 10, and data of low rewrite count is moved to the fixed memory 20.

First, the controller 30 monitors the rewrite count of data in both the removable memory 10 and the fixed memory 20 on, for example, a file basis (step ST1′).

The controller 30 compares the rewrite count of data with the reference value A (step ST2). As a result, the controller 30 performs the following processing.

If the rewrite count of data is lower than the reference value A (rewrite count<reference value A), data in the removable memory 10 is moved to the fixed memory 20, but data in the fixed memory 20 is maintained in the fixed memory 20 without being moved (step ST3′). On the other hand, if the rewrite count of data is equal to or higher than the reference value A (rewrite count≧reference value A), data in the removable memory 10 is maintained in the removable memory 10 without being moved, but data in the fixed memory 20 is moved to the removable memory 10 (step ST4′).

After that, the same steps ST5 to ST10 as in the first example of FIG. 6 are performed.

### [3-3] Exchange of Removable Memory 10

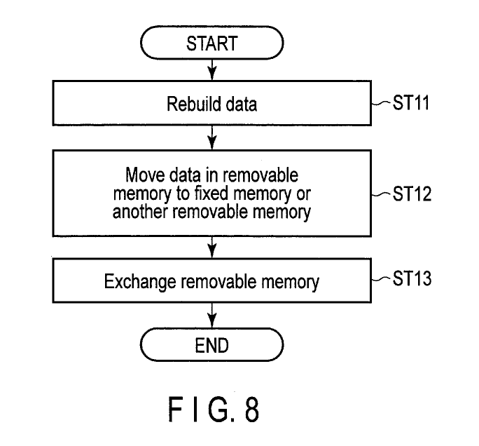

The exchange mode of the removable memory 10 will be described with reference to FIG. 8. The target of the exchange is the removable memory 10 for which the warning about the number of defective blocks more than the reference value B is given in step ST8 of FIG. 6 or 7.

First, the controller 30 rebuilds data in the removable memory 10 of the exchange target (step ST11).

The controller 30 moves the data in the removable memory 10 of the exchange target to the fixed memory 20 or the removable memory 10 excluded from the exchange target because of the absence of the warning about the number of defective blocks more than the reference value (step ST12).

After that, for example, the user detaches the second component 40b including the removable memory 10 of the exchange target from the first component 40a and exchanges it with a component including the new removable memory 10 (step ST13). Then, restart is performed.

Note that the reference value B having a certain margin may be provided, and the exchange mode may be started by causing the system (user) to issue a command of exchange mode to the semiconductor memory device 100 at the human discretion upon receiving the warning. Alternatively, the reference value B without a margin may be provided, and the exchange mode may be started automatically after the elapse of a predetermined time from reception of the warning about the number of defective blocks more than the reference value.

The data rebuild of step ST11 may be performed before the warning about the number of defective blocks more than the reference value B is given in step ST8 of FIG. 6 or 7.

The following processing is performed after the user exchanges for new second component 40b. When the new second component 40b is inserted into the first component 40a, a physical format and a logical format will be performed by the controller 30 as initialization to the removable memory 10 in the new second component 40b. Then, the controller 30 moves the data transmitted temporarily to the removable memory 10 in the second new component 40b from the fixed memory 20 or the removable memory 10 excluded from the exchange target.

### [4] NAND Bus 60

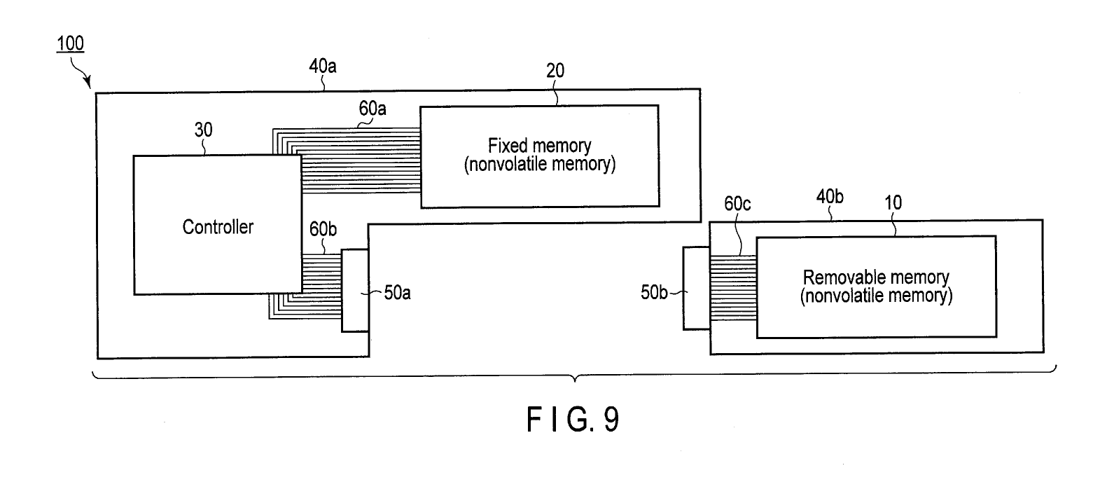

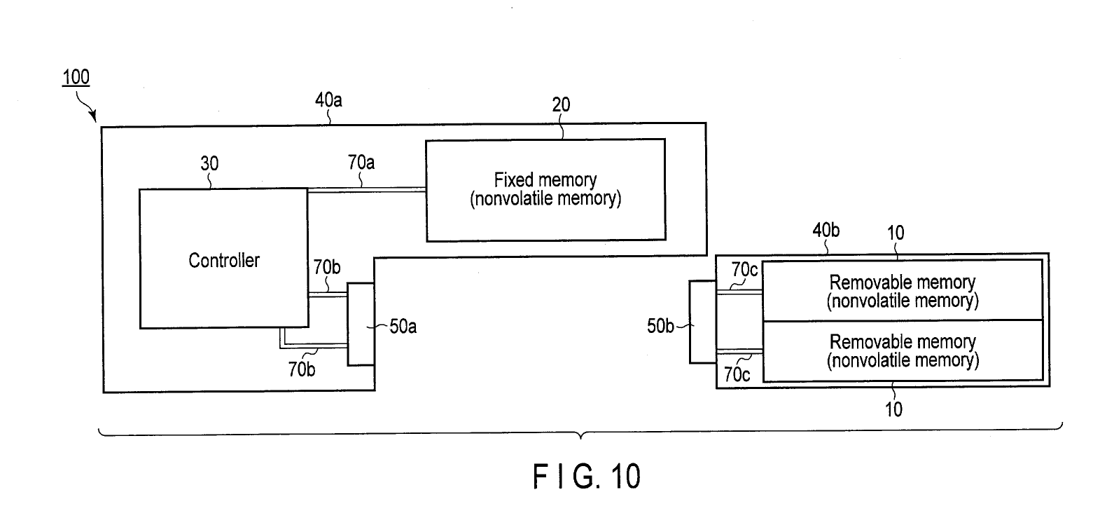

The NAND buses 60 that connect the controller 30 to the removable memory 10 and the fixed memory 20 will be described with reference to FIGS. 9 and 10.

The NAND buses 60 are used to exchange input/output signals (I/O1 to I/O8 or I/O1 to I/O16), command signals (/CE, CLE, ALE, /WE, /RE, /WP, and PSL), a ready/busy signal (RY/BY), and the like between the controller 30 and the NAND flash memories (removable memory 10 and fixed memory 20). Focus will be placed on the wirings for the input/output signals out of the NAND buses 60.

As shown in FIG. 9, the connection for the input/output signals between the controller 30 and the fixed memory 20 and the removable memory 10 may be done by parallel wirings (parallel buses). More specifically, the controller 30 and the fixed memory 20 are connected using parallel wirings 60a. The controller 30 and the connector 50a are connected using parallel wirings 60b. The connector 50b and the removable memory 10 are connected using parallel wirings 60c. In FIG. 9, when the input/output signals are I/O1 to I/O16, 16 wirings are used.

As shown in FIG. 10, the connection for the input/output signals between the controller 30 and the fixed memory 20 and the removable memory 10 may be done by serial wirings (serial buses). As the serial wirings, for example, differential serial wirings are used. More specifically, the controller 30 and the fixed memory 20 are connected using serial wirings 70a. The controller 30 and the connector 50a are connected using serial wirings 70b. The connector 50b and the removable memory 10 are connected using serial wirings 70c. As shown in FIG. 10, when the input/output signals I/O1 to I/O16 are connected by differential serial connection, two wirings are used, and two signal pins are provided for I/O1 to I/O16.

When the serial wirings are used, the number of signal pins and the number of wirings can be decreased, and the capacity of the memory connectable to each connector can thus be increased. In addition, since the number of signal pins and the number of wirings can be decreased, the connector portions can be made small.

In the semiconductor memory device 100, each of the removable memory 10 and the fixed memory 20 is formed from a plurality of memory packages, and N wirings per package are connected to the controller 30. For this reason, when there are M packages, a total of N×M wirings connect the controller 30 to each of the removable memory 10 and the fixed memory 20.

Note that the connection between the controller 30 and the removable memory 10 may be done using wirings of a type different from the wirings between the controller 30 and the fixed memory 20. For example, the controller 30 and the fixed memory 20 may be connected by parallel wirings, and the controller 30 and the removable memory 10 may be connected by differential serial wirings.

In the semiconductor memory device 100 of FIG. 10, the circuit board A on which the fixed memory 20 and the controller 30 are mounted in the first component 40a is different from the circuit board B on which the removable memory 10 is mounted in the second component 40b. The circuit board A is connected to the circuit board B by the connectors 50a and 50b.

The wiring structure (communication mode) between the controller 30 and the removable memory 10 is the same as the wiring structure (communication mode) between the controller 30 and the fixed memory 20. For example, both wiring structure is differential serial wiring which consists of conductor wiring of two, and its number of signal channels (transmission line) is equal. Both communication modes are a communication mode based on a NAND interface standard. Thereby, it becomes possible to unify the specification of the memory interface by the side of the controller 30.

The number of signal channels of the removable memory 10 and the fixed memory 20 is determined by the packaging density of the package and the accommodate capacity of the wiring of the circuit boards A and B. According to application, by adjusting these balances, it becomes possible to attain optimization of the capacity of all the nonvolatile memory and the entire transmission band.

### [5] Memory System

### [5-1] Arrangement Example 1

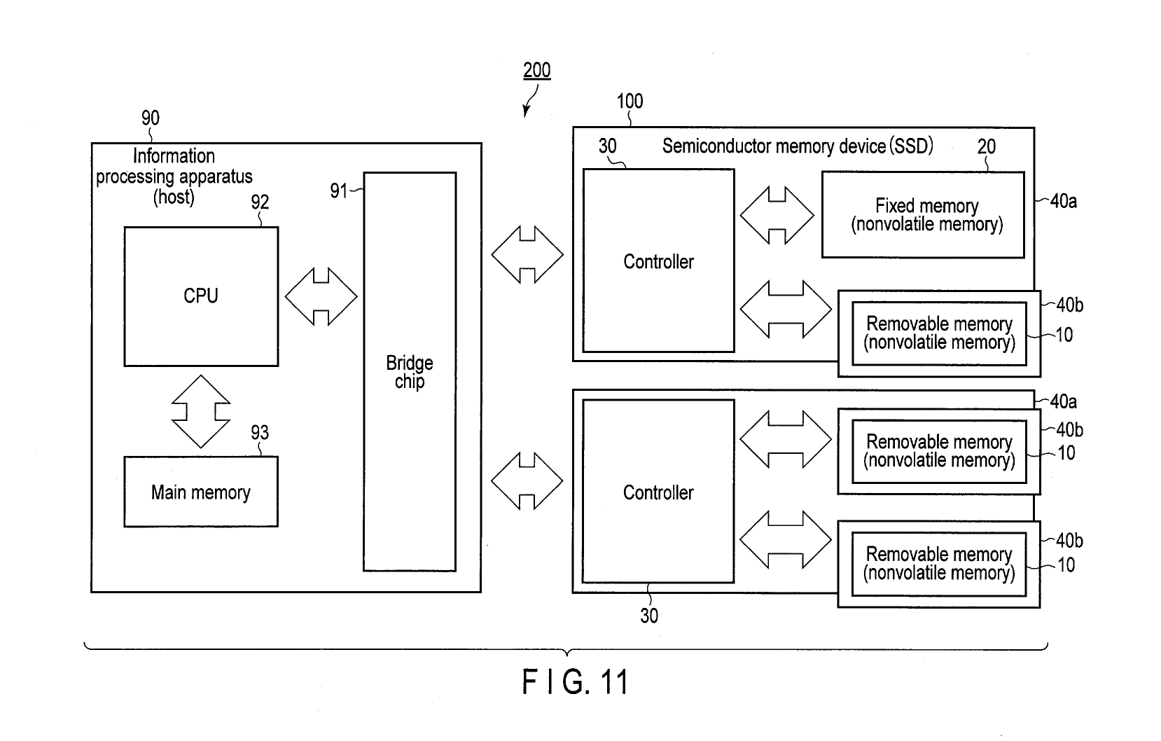

Arrangement example 1 of a memory system 200 will be described with reference to FIG. 11.

As shown in FIG. 11, the memory system 200 includes the semiconductor memory device (information storage devices) 100 and an information processing apparatus (host apparatus) 90.

The semiconductor memory device 100 is, for example, an SSD. As described above, the semiconductor memory device 100 includes the removable memory 10, the fixed memory 20, and the controller 30. The second component 40b including the removable memory 10 can be removable from the first component 40a including the fixed memory 20 and the controller 30.

The semiconductor memory device 100 can be used either while being mounted in the information processing apparatus 90 or as an additional device connected to the interface of the information processing apparatus 90.

The information processing apparatus 90 is an apparatus that communicates with the semiconductor memory device 100, and sends the instructions of data write, read, erase, and the like to the semiconductor memory device 100. The information processing apparatus 90 is, for example, a server, a router, or a personal computer. The information processing apparatus 90 includes a bridge chip 91, a CPU (Central Processing Unit) 92, and a main memory 93.

The bridge chip 91 controls data transmission/reception between the semiconductor memory device 100 and the information processing apparatus 90. The CPU 92 performs various kinds of operations and control in the information processing apparatus 90 and executes, for example, an OS (Operating System) and user programs. The main memory 93 is formed from, for example, a DRAM (Dynamic Random Access Memory), temporarily stores programs and data, and functions as the work area of the CPU 92.

### [5-2] Arrangement Example 2

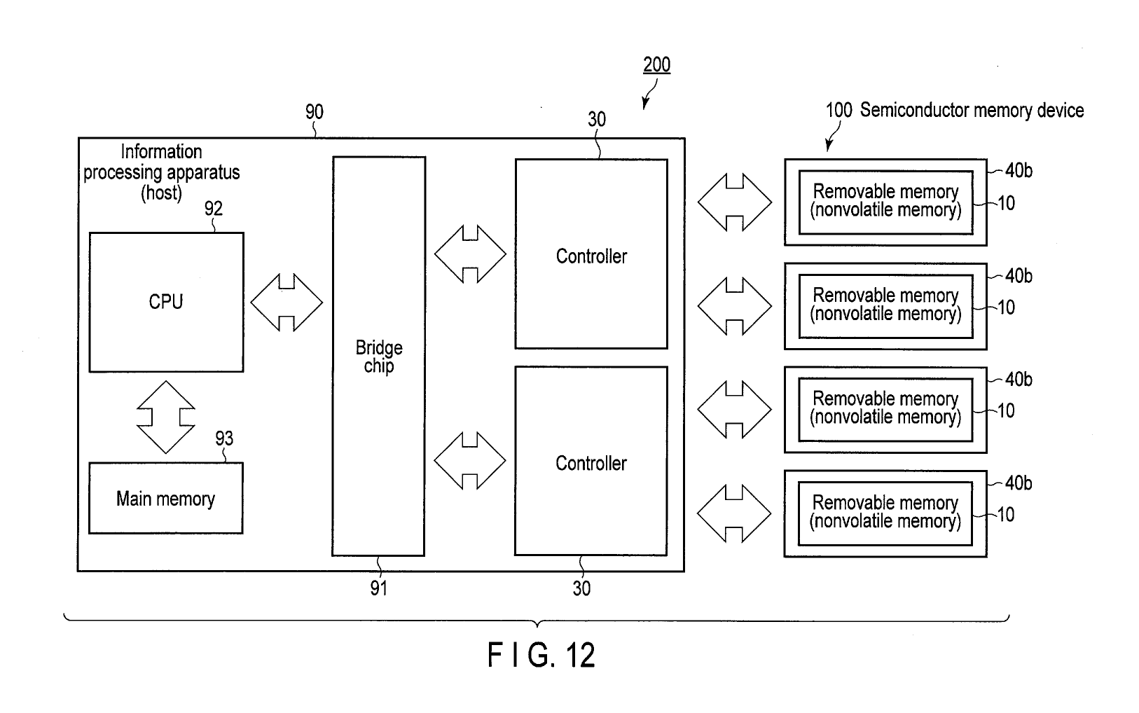

Arrangement example 2 of the memory system 200 will be described with reference to FIG. 12.

As shown in FIG. 12, arrangement example 2 is different from arrangement example 1 in that the controller 30 is provided on the side of the information processing apparatus 90. Hence, the component 40b including the removable memory 10 can be attached to the information processing apparatus 90 via a connector (not shown).

Note that the information processing apparatus 90 may include the fixed memory 20 to be controlled by the above-described controller 30.

### [6] Effects of Embodiment

The NAND flash memory has a limitation on the rewrite count. On the other hand, an enterprise SSD used in a data center or the like is required to have a high rewrite count depending on the application. Additionally, a customer of a data center is required to have a guarantee of a service period of about five years. For these reasons, the SSD ensures the required life by providing an extra capacity and uniforming the rewrite counts of blocks by wear leveling. However, as the flash memory cells are micronized recently, the endurance of cells lowers.

In the above-described embodiment, the component 40b including the removable memory 10 as a NAND flash memory is detachable from the semiconductor memory device 100 (component 40b), and only the component 40b can easily be exchanged in the semiconductor memory device 100. Since the semiconductor memory device 100 need not have an extra capacity, the cost can be reduced. In addition, the life of the semiconductor memory device 100 can be made long by exchanging only the component 40b including the removable memory 10.

Note that in this embodiment, the NAND flash memory has been exemplified as the nonvolatile semiconductor memory. However, the embodiment is also applicable to, for example, an ReRAM (Resistive Random Access Memory), a PCRAM (Phase Change Random Access Memory), an MRAM (Magnetic Random Access Memory), or the like. In this case, the same type of nonvolatile semiconductor memory may be used for the removable memory 10 and the fixed memory 20, and the nonvolatile semiconductor memory of a different type may be used for them. For example, the ReRAM may be used as the removable memory 10, NAND flash memory may be used as the fixed memory 20. While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a first component including a controller which issues an instruction complying with a NAND interface; and
a second component including a first NAND flash memory to be controlled by the instruction, the second component being removable from the first component.

2. The device according to claim 1, wherein the first component further includes a second NAND flash memory to be controlled by the instruction.

3. The device according to claim 2, wherein the controller stores data of a block whose rewrite count is not less than a reference value in the first NAND flash memory and data of a block whose rewrite count is less than the reference value in the second NAND flash memory.

4. The drive according to claim 2, wherein the controller writes data to the first NAND flash memory, and moves the data of a block in the first NAND flash memory whose rewrite count is less than the reference value to the second NAND flash memory.

5. The drive according to claim 2, wherein the controller writes data to the first NAND flash memory or the second NAND flash memory, moves the data of a block in the first NAND flash memory whose rewrite count is less than the reference value to the second NAND flash memory, and moves the data of a block in the second NAND flash memory whose rewrite count is not less than the reference value to the first NAND flash memory.

6. The device according to claim 3, wherein the controller changes the reference value according to free spaces of the first NAND flash memory and the second NAND flash memory.

7. The device according to claim 1, wherein the controller initializes to the first NAND flash memory, after the second component is inserted into the first component.

8. The device according to claim 1, wherein a wiring for input/output signal between the controller and the first NAND flash memory is a serial wiring.

9. The device according to claim 2, wherein a wiring for input/output signal between the controller and the second NAND flash memory is a serial wiring.

10. The device according to claim 2, wherein
the first NAND flash memory comprises a NAND flash memory of one of an eMLC type and an SLC type, and
the second NAND flash memory comprises a NAND flash memory of a TLC type.

11. The device according to claim 1, wherein the semiconductor memory device comprises a solid state drive.

12. A semiconductor memory device comprising:
a first circuit board;
a second circuit board being different from the first circuit board;
a first NAND flash memory mounted in the first circuit board;
a second NAND flash memory mounted in the second circuit board; and
a controller mounted in the second circuit board,
wherein wirings for input/output signal between the controller and the first NAND flash memory and between the controller and the second NAND flash memory are serial wirings.

13. The device according to claim 12, wherein the serial wirings are differential serial wirings.

14. The device according to claim 12, further comprising a connector connecting the first circuit board and the second circuit board.

15. The device according to claim 12, wherein
a wiring structure between the controller and the first NAND flash memory is a same as a wiring structure between the controller and the second NAND flash memory.

16. The device according to claim 12, wherein
a communication mode between the controller and the first NAND flash memory is a same as a communication mode between the controller and the second NAND flash memory.

17. A solid state drive comprising:
a first component including a controller; and
a second component including a first nonvolatile semiconductor memory to be controlled by the controller, the second component being removable from the first component.

18. The drive according to claim 17, wherein the first component further includes a second nonvolatile semiconductor memory to be controlled by the controller.

19. The device according to claim 17, wherein a wiring for input/output signal between the controller and the first nonvolatile semiconductor memory is a serial wiring.

20. The device according to claim 18, wherein a wiring for input/output signal between the controller and the second nonvolatile semiconductor memory is a serial wiring.
